(19) United States
(12) Patent Application Publication
(10) Pub. No.: US 2019/0252564 A1
(43) Pub. Date: Aug. 15, 2019

(54) PHOTOVOLTAIC POWER GENERATION AND STORAGE DEVICE, AND METHOD OF MANUFACTURING SAME

(71) Applicant: BEIJING APOLLO DING RONG SOLAR TECHNOLOGY CO., LTD., Beijing (CN)

(72) Inventors: Rouin FARSHCHI, Palo Alto, CA (US); Dmitry POPLAVSKYY, San Jose, CA (US)

(21) Appl. No.: 15/893,963

(22) Filed: Feb. 12, 2018

(51) Int. Cl. H01L 31/053; H01L 31/02; H01L 31/0392; H01L 31/0445; H01L 31/032; H01L 31/0224; H01L 31/18; H01M 10/46; H01M 10/0565; H01M 10/0585; H01M 4/38; H01M 4/48; H01M 10/0566

(52) U.S. Cl. CPC H01L 31/053; H01M 2300/0045; H01L 31/03928; H01L 31/0445; H01L 31/0322; H01L 31/022466; H01L 31/02021; H01L 31/1876; H01L 31/0201; H01M 10/465; H01M 10/0565; H01M 10/0585; H01M 4/38; H01M 4/483; H01M 10/0566; H01M 2220/10; H01M 2300/0085; H01M 2300/0082; H01L 31/02013

(57) ABSTRACT

A photovoltaic power generation and storage (PPGS) device includes an electrically conductive substrate, a solar cell disposed on a first side of the substrate, the solar cell including an absorber layer disposed between an anode and a cathode, and a solid-state battery printed on an opposing second side of the substrate, the battery including an electrolyte layer disposed between an anode and a cathode. The method of forming the PPGS device includes forming a semiconductor material stack including a solar cell p-n junction on a first surface of a conductive web, and printing solid-state batteries on an opposing second surface of at least a portion of the conductive web.

### FIELD

The present disclosure is directed generally to photovoltaic power generation and storage devices, arrays including a plurality of such devices, and methods for manufacturing the same.

### BACKGROUND

Photovoltaic cells (e.g., solar cells) are currently being developed as a source of “green” energy. However, a fundamental shortcoming of solar cells is the intermittent nature of the power produced thereby. Accordingly, solar cell power generation systems generally require a secondary energy source, e.g., connection to a power grid, to provide energy at night and in periods of low solar radiation. In addition, during periods of peak power generation, solar cell systems may generate more power than required for local consumption, requiring utilities to distribute the surplus power to the power grid.

### SUMMARY

According to various embodiments of the present disclosure, provided is a photovoltaic power generation and storage (PPGS) device comprising: an electrically conductive substrate; a solar cell disposed on a first side of the substrate, the solar cell comprising an absorber layer disposed between an anode and a cathode; and a solid-state battery printed on an opposing second side of the substrate. The battery comprises an electrolyte layer disposed between an anode and a cathode.

According to various embodiments of the present disclosure, provided is a method of making a photovoltaic power generation and storage (PPGS) array, the method comprising: forming a semiconductor material stack including a solar cell p-n junction on a first surface of a conductive web; and printing solid-state batteries on an opposing second surface of at least a portion of the conductive web.

### BRIEF DESCRIPTION OF THE DRAWINGS

FIG. 1 is a vertical cross-sectional view of a photovoltaic power generation and storage device 100, according to various embodiments of the present disclosure.

FIG. 2A is a top plan view showing additional components of the device 100, FIG. 2B is a vertical cross-sectional view taken along line I-I of FIG. 2A, and FIG. 2C is a vertical cross-sectional view taken along line II-II of FIG. 2A.

FIG. 3A is a top plan view of electrically connected photovoltaic storage devices 100A, 100B, according to various embodiments of the present disclosure, and FIG. 3B is a sectional view taken along line of FIG. 3A.

FIG. 4A is a bottom plan view of an array 110 including devices 100 electrically connected and disposed in a tiled configuration, FIG. 4B is a cross-sectional view taken along line IV-IV of FIG. 4A, and FIGS. 4C and 4D are respective component electric connection schematic view and circuit schematic view showing the electrical connection of the array 110 of FIG. 4A.

FIG. 5 shows an exemplary apparatus 1000 for forming the solar cells 10 on the substrate 12 illustrated in FIG. 1.

FIGS. 6A-6D illustrate a silk-screen method of forming a solid-state battery, according to various embodiments of the present disclosure.

FIGS. 7A-7D illustrate an inkjet printing method of forming a solid-state battery, according to various embodiments of the present disclosure.

### DETAILED DESCRIPTION

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a direct physical contact between a surface of the first element and a surface of the second element. As used herein, an element is “configured” to perform a function if the structural components of the element are inherently capable of performing the function due to the physical and/or electrical characteristics thereof.

It will also be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Ranges may be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. In some embodiments, a value of “about X” may include values of +/−1% X. It will be further understood that the endpoints of each of the ranges are significant both in relation to the other endpoint, and independently of the other endpoint. Herein, “substantially all” of an element may refer to an amount of the element ranging from 98-100% of the total amount of the element. In addition, when a component is referred to as being “substantially free” of an element, the component may be completely free of the element or may include a trace amount (e.g., 1% or less) of the element.

A “thin-film” photovoltaic material refers to a polycrystalline or amorphous photovoltaic material that is deposited as a layer on a substrate that provides structural support. The thin-film photovoltaic materials are distinguished from single crystalline semiconductor materials that have a higher manufacturing cost. Some of the thin-film photovoltaic materials that provide high conversion efficiency include chalcogen-containing compound semiconductor material, such as copper indium gallium selenide (CIGS).

Thin-film photovoltaic cells (also known as solar cells) may be manufactured using a roll-to-roll coating system based on sputtering, evaporation, or chemical vapor deposition (CVD) techniques. A thin foil substrate, such as a foil web substrate, is fed from a roll in a linear belt-like fashion through the series of individual vacuum chambers or a single divided vacuum chamber where it receives the required layers to form the thin-film photovoltaic cells. In such a system, a foil having a finite length may be supplied on a roll. The end of a new roll may be coupled to the end of a previous roll to provide a continuously fed foil layer.

Batteries can help reduce the reliance of solar systems on the power grid by storing excess generated power for later use. However, adding batteries to solar cell systems, such as roof-top solar panel systems, can significantly increase system and installation costs. In addition, standalone battery units may also have a significant footprint, which may further complicate system installation. In various embodiments of the present disclosure, the battery layers are printed on the back side of a solar cell substrate to decrease battery footprint and to decrease system installation costs.

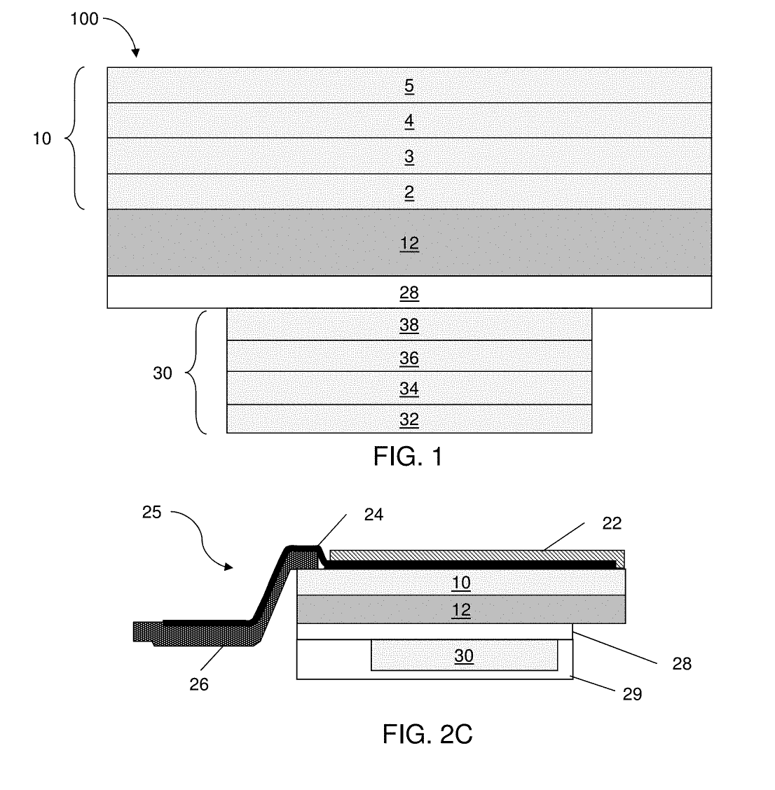

FIG. 1 is a vertical cross-sectional view of a photovoltaic power generation and storage device 100, according to various embodiments of the present disclosure. Referring to FIG. 1, the device 100 includes a solar cell 10 and a battery 30 disposed on opposing first and second sides of a substrate 12. The solar cell 10 may completely cover the first side of the substrate, in some embodiments. The solar cell 10 may include a first electrode 2 (e.g., anode or positive electrode), a p-doped semiconductor layer 3, an n-doped semiconductor layer 4, a second electrode 5 (e.g., cathode or negative electrode), and an optional antireflective (AR) layer. The anode 2, the cathode 5, the p-doped semiconductor layer 3, the n-doped semiconductor layer 4, and the optional AR layer may be in the form of a stack of various films that form a photovoltaic structure.

The substrate 12 may be formed of a flexible, electrically conductive material, such as a metal or metal alloy foil. The substrate 12 may be formed of aluminum, titanium, or a metal alloy such as stainless steel. The substrate 12 may be formed by cutting a metallic web substrate that is fed through a system including one or more process modules, as discussed below in detail. The substrate 12 may comprise a part of the anode electrode 2 of the cell 10. Thus, the anode 2 of the cell 10 may be referred to as a back electrode. Alternatively, the conductive substrate 12 may be an electrically conductive or insulating polymer foil. Still alternatively, the substrate 12 may be a stack of a polymer foil and a metallic foil. The thickness of the substrate 12 can be in a range from 100 microns to 2 mm, although lesser and greater thicknesses can also be employed.

The anode 2 may comprise any suitable electrically conductive layer or stack of layers. For example, the anode 2 may include a metal layer, which may be, for example, molybdenum. Alternatively, a stack of molybdenum and sodium and/or oxygen doped molybdenum layers may be used instead, as described in U.S. Pat. No. 8,134,069, which is incorporated herein by reference in its entirety. The anode 2 can have a thickness in a range from 500 nm to 1 micron, although lesser and greater thicknesses can also be employed. The anode 2 may directly, physically contact the first (i.e., top) surface of the substrate 12.

The p-doped semiconductor layer 3 can include a p-type, sodium doped copper indium gallium selenide (CIGS), which functions as a semiconductor absorber layer. The thickness of the p-doped semiconductor layer 3 can be in a range from 1 microns to 5 microns, although lesser and greater thicknesses can also be employed.

The n-doped semiconductor layer 4 includes an n-doped semiconductor material such as CdS, ZnS, ZnSe, or an alternative metal sulfide or a metal selenide. The thickness of the n-doped semiconductor layer 4 is typically less than the thickness of the p-doped semiconductor layer 3, and can be in a range from 50 nm to 100 nm, although lesser and greater thicknesses can also be employed. The junction between the p-doped semiconductor layer 3 and the n-doped semiconductor layer 4 is a p-n junction. The n-doped semiconductor layer 4 can be a material which is substantially transparent to at least part of the solar radiation. The n-doped semiconductor layer 4 is also referred to as a buffer layer. Other semiconductor materials, such as GaAs, silicon, CdTe, etc., may be used for the p-doped and/or n-doped semiconductor layers 3, 4.

The cathode 5 may be formed of one or more layers of a transparent conductive material. Exemplary transparent conductive materials include ZnO, indium tin oxide (ITO), Al doped ZnO (“AZO”), or a combination or stack of higher resistivity AZO and lower resistivity ZnO, ITO and/or AZO layers.

The optional AR layer can decrease the amount of light that is reflected off the top surface of the photovoltaic cell 10, which is the surface that is located on the opposite side of the substrate 12. In one embodiment, the AR layer can be a coating deposited directly on the top surface of the second electrode 5. Alternatively or additionally, a transparent cover glass or polymer layer can be disposed over the photovoltaic cell in a final product, and an antireflective coating can be formed on either side, or on both sides, of the transparent cover glass. A separator dielectric layer 28 may be disposed on the second (i.e., back) side of the substrate 12.

According to various embodiments of the present disclosure, the battery 30 may be a flexible and rechargeable, solid-state battery. In some embodiments, the battery 30 may be a Zn-based solid-state battery. The battery 30 may be formed by printing layers on a second side of the substrate 12 opposing a first side of the substrate 12 upon which the solar cell 10 is disposed. In particular, the battery 30 may be disposed on the separator dielectric layer 28 which is located on the second side of the substrate 12. The battery 30 may cover a portion of the second side of the substrate 12, such that a portion of the substrate 12 remains outside of the perimeter of the battery 30.

The battery 30 may include a first electrode layer 32 (e.g., anode or negative electrode), an electrolyte layer 34, and a second electrode layer 36 (e.g., cathode or positive electrode). The battery 30 may also include a current collector 38 disposed on the cathode 36.

The electrolyte layer 34 may be a non-aqueous gel electrolyte layer that is coupled to the anode 32 and the cathode 36, such that the electrolyte layer 34 physically separates the anode 32 and the cathode 36. The anode 32 may be electrically connected to the cathode 36 of an adjacent battery 30. The electrolyte layer 34 may comprise a composition configured to provide ionic communication between the anode 32 and the cathode 36 by facilitating the transmission of multivalent ions therebetween.

In some embodiments, the electrolyte layer 34 may be a gel electrolyte including a polymer network in which a liquid electrolyte is disposed. The liquid electrolyte may include one or more electrolyte salts dissolved in an ionic liquid. The electrolyte salts may be configured to provide divalent or multivalent ions that are to be transported through the electrolyte gel.

The polymer network may include one or more polymers selected from poly(vinylidene fluoride) (PVDF), poly(vinylidene fluoride) hexafluorophosphate (PVDF-HFP), polyvinyl alcohol (PVA), poly(ethylene oxide) (PEO), poly(acrylo-nitrile) (PAN), and poly(methyl methacrylate) (PMMA), epoxy derivatives, and silicone derivatives.

The liquid electrolyte may include a class of materials known as ionic liquids. The ionic liquids may have a low electrical conductivity (<5 mS/cm), a large electrochemical stability window (>1 V), the ability to dissolve electrolyte salts, and a viscosity compatible with desired processing methods. One exemplary ionic liquid comprises 1-butyl-3-methylimidazolium trifluoromethanesulfonate (C₉H₁₅F₃N₂O₃S).

The ionic liquid may comprise cations such as imidazolium variants, pyrrolidinium variants, ammonium variants, pyridinium variants, piperidinium variants, phosphonium variants, and sulfonium variants, and anions such as chlorides, tetrafluoroborate (BF₄⁻), trifluoroacetate (CF₃CO₂⁻), trifluoromethansulfonate (CF₃SO₃⁻), hexafluorophosphate (PF₆⁻), bis(trifluoromethylsulfonyl)amide (NTf₂⁻), bis(fluorosulfonyl)imide (N(SO₂F)₂⁻). In some embodiments, the ionic liquid comprises cations selected from the group consisting of zinc ions (Zn²⁺), aluminum (Al³⁺), magnesium (Mg²⁺), and yttrium (Y²⁺).

The liquid electrolyte may have an ionic conductivity greater than 1 mS/cm, and preferably ranging between 2 mS/cm and 3.5 mS/cm, and more preferably between 2.3 mS/cm and 2.7 mS/cm. In some embodiments, the liquid electrolyte has an electrolyte salt concentration between 0.2 and 0.75 M in ionic liquid, and preferably between 0.4 and 0.75 M, and more preferably between 0.45 and 0.65 M. The ionic liquid electrolyte concentration in the polymer gel can be defined as % weight of ionic liquid electrolyte in the polymer gel. In one embodiment, the preferred % weight of ionic liquid electrolyte to polymer is greater than 20%, and preferably ranging between 25% and 90%, and more preferably between 40 and 85%.

The anode 32 may comprise a metal which emits multivalent ions when undergoing an oxidation reaction with the ionic liquid electrolyte. For example zinc metal forms zinc ions of divalent charge as a result of an oxidation reaction with the ionic liquid electrolyte. The anode 32 may also comprise aluminum, magnesium, yttrium, combinations thereof, or the like. The anode material composition may also comprise of multiple morphological features (e.g. zinc flakes and spherical particles and nanoparticles) to increase electrochemical capacity.

In various embodiments, the cathode 36 includes, as a major component, a metal oxide. For example, the cathode 36 may comprise vanadium pentoxide (V₂O₅) particles, manganese dioxide (MnO₂) particles, cobalt oxide (CoOₓ) particles, lead oxide (PbOₓ) particles, or the like. In yet other embodiments, the cathode 36 has, as a significant component, particles of any metal oxide that can absorb and release ions that come from the cathode 36. The current collector 38 may include a conductive material such as a metal or carbon.

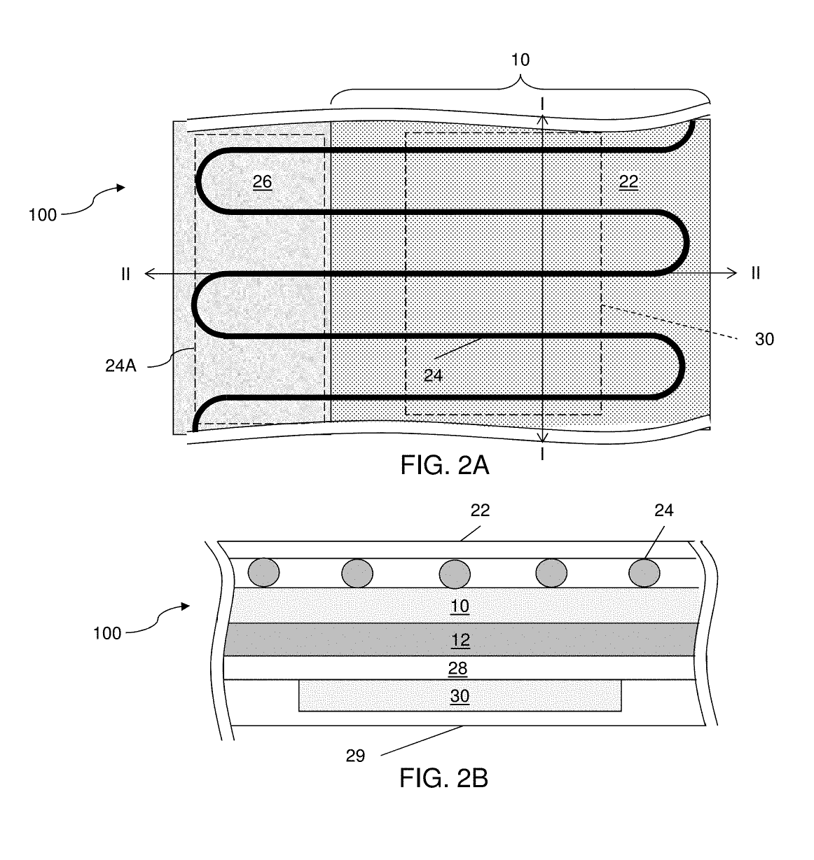

FIG. 2A is a top plan view showing additional components of the device 100. FIG. 2B is a vertical cross-sectional view taken along line I-I of FIG. 2A, and FIG. 2C is a vertical cross-sectional view taken along line II-II of FIG. 2A.

Referring to FIGS. 2A-2C, the device 100 may include an interconnect 25, including a conductive wire 24, the first dielectric layer 22, and/or a second dielectric layer 26, to electrically connect the solar cell 10 to an adjacent solar cell in series, as discussed in detail below. The first dielectric layer 22 may be disposed on an upper surface of the wire 24, and the second dielectric layer 26 may be disposed on a lower surface of the conductive wire 24. The device 100 may also include a third (i.e., separator) dielectric layer 28 disposed between the battery 30 and the substrate 12, and a fourth (e.g., cover) dielectric layer 29 covering a lower surface of the battery 30. The dielectric layers 22, 26, 28, 29 may be formed of a dielectric material, such as a polymer or the like. In some embodiments, one or more of the dielectric layers 22, 26, 28, 29 may be substantially transparent. In one embodiment, the dielectric layers 22 and 26 may be substantially transparent while the dielectric layers 28 and 29 may be opaque since they are located on the back side of the substrate 12. In some embodiments, one or more of the dielectric layers 22, 26, 28, 29 may be formed of a flexible material, such as a transparent polymeric film, a transparent non-polymeric film, a transparent oligomer film, or a combination thereof.

The wire 24 may be wire disposed in a continuous serpentine pattern on the upper surface of the solar cell 10, such that contact resistance between the wire 24 and the cathode 5 (see FIG. 1) is reduced. However, the wire 24 is not limited to any particular pattern. For example, the wiring could be disposed in a zig-zag pattern or any other suitable pattern configured to increase the contact area between the wire 24 and the solar cell 10. A portion 24A of the wire 24 extends beyond an edge of the solar cell 10 and is disposed on the second dielectric layer 26. An edge of the second dielectric layer 26 may be attached to an edge of the upper surface of the solar cell 10. The second dielectric layer 26 may have an adhesive coating on each side in areas that contact the photovoltaic cells 10. In an alternative embodiment, the dielectric layers 22, 26 may comprise pressure sensitive adhesive (PSA) sheets.

The wire 24 may have a non-rectangular and substantially uniform cross-sectional shape in a plane perpendicular to the local lengthwise direction. For example, the wire 24 can have a substantially circular cross-sectional shape or an elliptical cross-sectional shape. The thickness of the wire 24, which is defined as the maximum dimension of the non-rectangular and substantially uniform cross-sectional shape, can be in a range from 30 microns to 3 mm. In one embodiment, the thickness of the wire 24 can be in a range from 60 microns to 1.5 mm. In one embodiment, the thickness of the wire 24 can be in a range from 120 microns to 750 microns. In case the non-rectangular and substantially uniform cross-sectional shape is a circle, the maximum lateral dimension can be the diameter of the zig-zag conductive wire 24. Alternatively, the wire 24 may have a rectangular cross sectional shape. In other embodiments, conductors other than the wire 24, such as conductive traces or strips, may be used in place of the conductive wire 24.

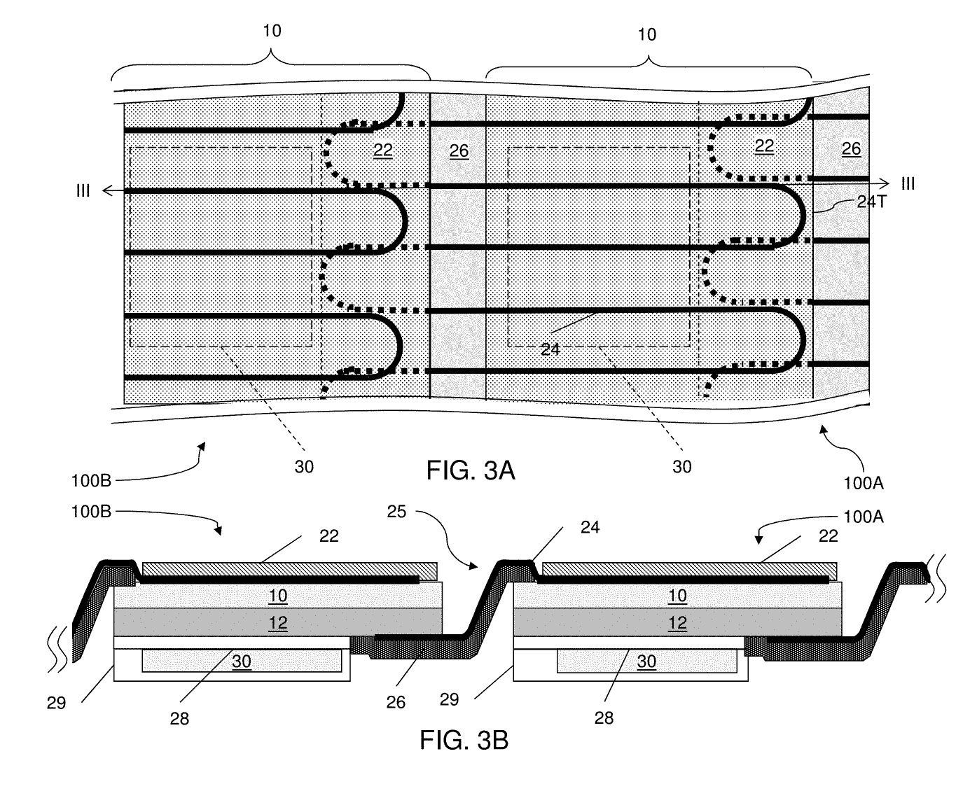

FIG. 3A is a top plan view of electrically connected photovoltaic power generating and storage devices 100A, 100B, according to various embodiments of the present disclosure. FIG. 3B is a sectional view taken along line of FIG. 3A. The devices 100A, 100B are similar to the device 100 of FIGS. 1-2C, and thus, will not be described in detail.

Referring to FIGS. 3A and 3B, the devices 100A, 100B are disposed in a “tiled” (e.g., “shingled”) configuration where the solar cell 10 of the device 100A is electrically connected to the solar cell 10 of the device 100B by an interconnect 25. In particular, a first portion of a wire 24 of the interconnect 25 is electrically connected to the cathode of a solar cell 10 of the device 100A. The interconnect 25 may include a first dielectric layer 22 configured to adhere the first portion of the wire 24 to the solar cell of the device 100A.

A second portion of the wire 24 extends from the device 100A and contacts a lower surface of the conductive substrate 12 of the device 100B. In particular, the second portion of the wire 24 is electrically connected to the anode of the solar cell 10 of the device 100B, via the substrate 12. The interconnect 25 may include a second dielectric layer 26 configured to adhere the second portion of the wire 24 to the bottom surface of the substrate 12. Accordingly, the interconnect 25 physically and electrically connects the solar cells 10 in series. As can be seen in FIGS. 3A and 3B, the flexibility of the interconnect 25 allows for the interconnect to be bent to connect adjacent devices 100A, 100B, such that portions of adjacent interconnects 25 overlap one another with a solar cell 10 and substrate 12 being disposed therebetween.

The configuration of the interconnect 25 may be varied, and thus, is not limited to the configuration described above. Other interconnect configurations may be found in U.S. patent application Ser. No. 15/189,818, which is incorporated herein by reference, in its entirety. The devices 100A, 100B are shown as being laterally separated for clarity. However, the devices 100A, 100B may be laterally overlapped in the shingled configuration, such that an edge of the bottom surface of the substrate 12 of the device 100B overlaps with an edge of the top surface of the solar cell 10 of the device 100A.

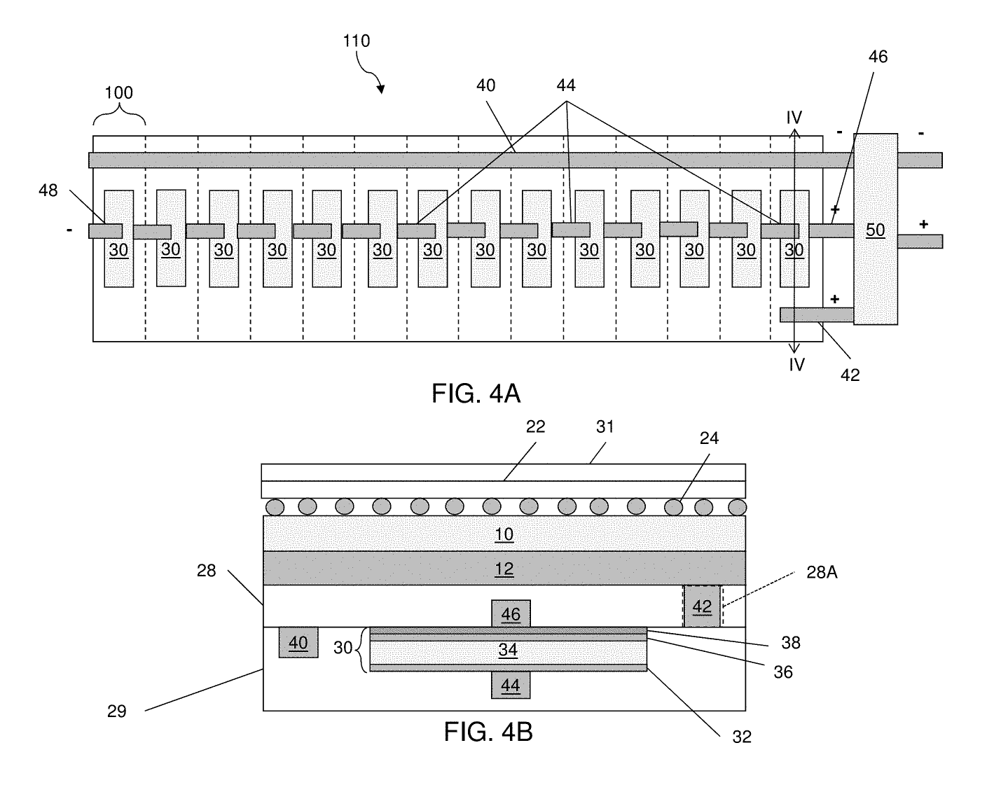

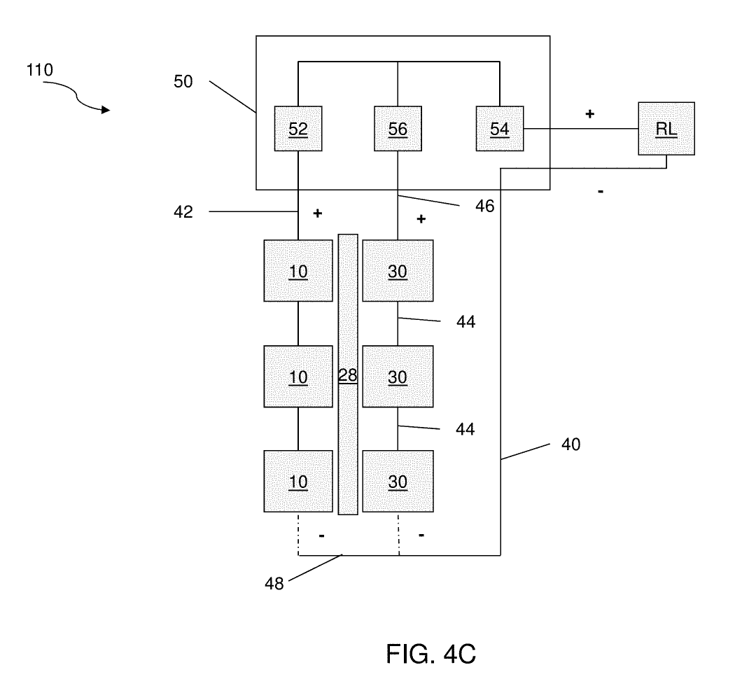

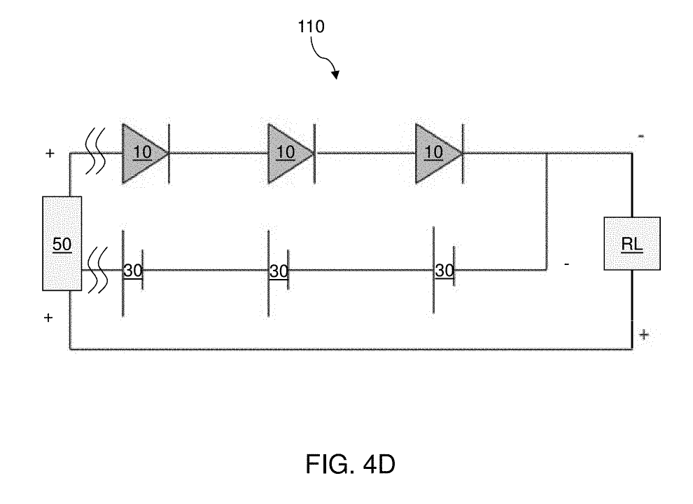

FIG. 4A is a bottom plan view of an array 110 including devices 100 electrically connected and disposed in a tiled configuration, according to various embodiments of the present disclosure. FIG. 4B is a cross-sectional view taken along line IV-IV of FIG. 4A, and FIGS. 4C and 4D are respective component electric connection schematic view and schematic circuit view showing the electrical connection of the array 110 of FIG. 4A.

Referring to FIGS. 4A-4D, the array includes a plurality of the devices 100 tiled (e.g., shingled) on one another. The devices 100 are electrically connected in series by interconnects 25, as described above (see FIGS. 3A, 3B). The array 110 also includes a first bus bar (e.g., line) 40 that is electrically connected to the solar cells 10 of each device 100. In particular, the first bus bar 40 may be disposed on the third dielectric layer 28 and may extend around an edge of the array 110 to electrically contact the cathode one of the solar cells 10 and/or a corresponding interconnect 25. Accordingly, the first bus bar 40 may operate as a negative terminal of the solar cells 10.

The array 110 may include a second bus bar (e.g., line) 42 that is electrically connected to a bottom surface of the substrate 12 through an opening 28A formed in the third dielectric layer 28. As noted above, each substrate 12 may be electrically connected to the anode of a corresponding solar cell 10. Accordingly, the second bus bar 42 may serve as a positive terminal for the serially connected solar cells 10 of the devices 100.

The array 110 may also include third bus bars (e.g., lines) 44, a fourth bus bar (e.g., line) 46, and a fifth bus bar (e.g., line) 48. In particular, the third bus bars 44 may each electrically connect the anode 32 and cathode 36 or current collector 38 of adjacent batteries 30, such that the batteries 30 are connected in series as a battery string. Thus, the third bus bars 44 function as battery interconnects. The fourth bus bar 46 may electrically contact a cathode 36 or current collector 38 of one of the batteries 30, and may operate as a positive terminal of the serially connected batteries 30. The fifth bus bar 48 may extend around an edge of the array 110 to electrically connect the negative electrodes of the battery 30 and solar cell 10 of a first one of the devices 100 disposed at an end of the array 110. In particular, the fifth bus bar 48 may electrically connect the anode 32 of the battery 30 to the cathode 5 of the solar cell 10 of the first device 100. As such, the fifth bus bar 48 may operate as a negative terminal of the serially connected batteries 30. In one embodiment, the fifth bus bar 48 may be electrically connected to the first bus bar 40, such that the first bus bar 40 may operate as a negative terminal for the batteries 30 and the solar cells 10.

The fourth (e.g., cover) dielectric layer 29 may be configured to cover (e.g., encapsulate) the third dielectric layer 28, the batteries 30 and the bus bars 40, 42, 44. In some embodiments, the array 110 may include a fifth dielectric layer 31 configured to encapsulate the first dielectric layer 22. The fifth dielectric layer 31 may be formed of transparent, flexible, dielectric materials, as described above.

The array 110 may also include a control unit 50 configured to control current flow from the array 110 to a resistive load RL, and to control charging of the batteries 30. In particular, as shown in FIG. 4C, the control unit 50 may include a first switch 52, a second switch 54, and a third switch 56 configured to control current flow through the bus bars 40, 42, 44. The first switch 52 may be configured to control current flow through the solar cells 10. The second switch 54 may be configured to control current flow to the load RL, and the third switch 56 may be configured to control current flow through the batteries 30.

The control unit 50 may have various modes of operation according to whether the load RL is applied to the array 110 and the amount of power generated by the solar cells 10. For example, the control unit 50 may have a first mode of operation, when the solar cells 10 are generating power due to exposure to light and the load RL is applied to the array 110. In particular, in the first mode, the control unit 50 may be configured to open the third switch 56 and close the first and second switch 52, 54, such that power generated by the solar cells 10 is provided to the load RL, without charging the batteries 30.

The control unit 50 may have a second mode of operation, when the solar cells 10 are generating power and the load RL is not applied to the array 110. In particular, in the second mode, the control unit 50 may close the first and third switches 52, 56, and open the second switch 54, such that the power is provided to and stored in the batteries 30 and no power is applied to the load RL.

The control unit 50 may have a third mode of operation, when the solar cells 10 are not generating power and the load RL is applied to the array 110. In particular, in the third mode, the control unit 50 may close the second and third switches 54, 56, and open the first switch 52, such that power stored in the batteries 30 is applied to the load RL.

In some embodiments, the array 110 may include a diode (not shown) to prevent current from flowing along the first bus line 40 back to the solar cells 10. In general, the control unit 50 is configured to disconnect the solar cells 10 from the batteries 30 by opening the first switch 52 and/or the third switch 56 when the voltage on the cells drops below a threshold voltage to present the batteries 30 from discharging into the solar cells 10.

### Solar Cell Formation

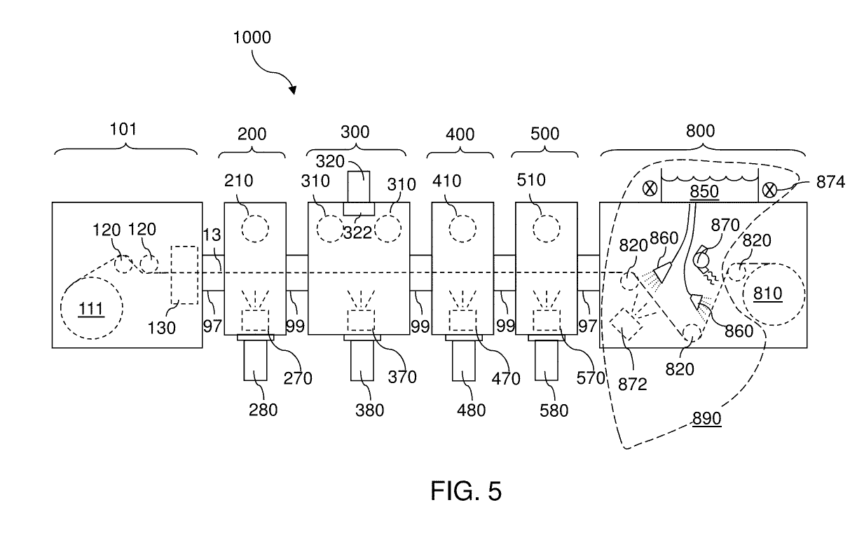

FIG. 5 shows an exemplary apparatus 1000 for forming the solar cell 10 on the substrate 12 illustrated in FIG. 1. Referring to FIG. 5, the apparatus 1000 includes an input unit 101, a first process module 200, a second process module 300, a third process module 400, a fourth process module 500, and an output unit 800 that are sequentially connected to accommodate a continuous flow of a conductive web substrate 13 in the form of a web foil substrate layer through the apparatus. The modules 101, 200, 300, 400, 500 may comprise the modules described in U.S. Pat. No. 9,303,316, issued on Apr. 5, 2016, incorporated herein by reference in its entirety, or any other suitable modules. The first, second, third, and fourth process modules 200, 300, 400, 500 can be under vacuum by first, second, third, and fourth vacuum pumps 280, 380, 480, 580, respectively. The first, second, third, and fourth vacuum pumps 280, 380, 480, 580 can provide a suitable level of respective base pressure for each of the first, second, third, and fourth process modules 200, 300, 400, 500, which may be in a range from 1.0×10⁻⁹ Torr to 1.0×10⁻² Torr, and preferably in range from 1.0×10⁻⁹ Torr to 1.0×10⁻⁵ Torr.

Each neighboring pair of process modules 200, 300, 400, 500 is interconnected employing a vacuum connection unit 99, which can include a vacuum tube and an optional slit valve that enables isolation while the web substrate 13 is not present. The input unit 101 can be connected to the first process module 200 employing a sealing connection unit 97. The last process module, such as the fourth process module 500, can be connected to the output unit 800 employing another sealing connection unit 97.

The web substrate 13 can be a metallic or polymer web foil that is fed into a system of process modules 200, 300, 400, 500 as a web for deposition of material layers thereupon to form the photovoltaic cell 10. The web substrate 13 can be fed from an entry side (i.e., at the input module 101), continuously move through the apparatus 1000 without stopping, and exit the apparatus 1000 at an exit side (i.e., at the output module 800). The web substrate 13, in the form of a web, can be provided on an input spool 111 provided in the input module 101.

The web substrate 13, as embodied as a metal or polymer web foil, is moved throughout the apparatus 1000 by input-side rollers 120, output-side rollers 820, and additional rollers (not shown) in the process modules 200, 300, 400, 500, vacuum connection units 99, or sealing connection units 97, or other devices. Additional guide rollers may be used. Some rollers 120, 820 may be bowed to spread the web 13, some may move to provide web steering, some may provide web tension feedback to servo controllers, and others may be mere idlers to run the web in desired positions.

The input module 101 can be configured to allow continuous feeding of the web substrate 13 by adjoining multiple foils by welding, stapling, or other suitable means. Rolls of web substrate 13 can be provided on multiple input spools 111. A joinder device 130 can be provided to adjoin an end of each roll of the web substrate 13 to a beginning of the next roll of the web substrate 13. In one embodiment, the joinder device 130 can be a welder or a stapler. An accumulator device (not shown) may be employed to provide continuous feeding of the web substrate 13 into the apparatus 1000 while the joinder device 130 adjoins two rolls of the web substrate 13, as described in U.S. Pat. No. 7,516,164.

In one embodiment, the input module 101 may perform pre-processing steps. For example, a pre-clean process may be performed on the web substrate 13 in the input module 101. In one embodiment, the web substrate 13 may pass by a heater array (not shown) that is configured to provide at least enough heat to remove water adsorbed on the surface of the web substrate 13. In one embodiment, the web substrate 13 can pass over a roller configured as a cylindrical rotary magnetron. In this case, the front surface of web substrate 13 can be continuously cleaned by DC, AC, or RF sputtering as the web substrate 13 passes around the roller/magnetron. The sputtered material from the web substrate 13 can be captured on a disposable shield. Optionally, another roller/magnetron may be employed to clean the back surface of the web substrate 13. In one embodiment, the sputter cleaning of the front and/or back surface of the web substrate 13 can be performed with linear ion guns instead of magnetrons. Alternatively or additionally, a cleaning process can be performed prior to loading the roll of the web substrate 13 into the input module 101. In one embodiment, a corona glow discharge treatment may be performed in the input module 101 without introducing an electrical bias.

The output module 800 can include an output spool 810, which winds the web substrate 13 including the deposited photovoltaic layers 2, 3, 4, 5 thereon. The coated web substrate 13 may be subsequently cut to form individual solar cells 10 disposed on a conductive substrate 12. In the alternative, the web substrate 13 may be cut into conductive substrates (e.g., substrate sheets) 12 in the output module 800 without being wound on spool 810.

The input spool 111 and optional output spool 810 may be actively driven and controlled by feedback signals to keep the web substrate 13 in constant tension throughout the apparatus 1000. In one embodiment, the input module 101 and the output module 800 can be maintained in the air ambient at all times while the process modules 200, 300, 400, 500 are maintained at vacuum during layer deposition. The web substrate 13 may be treated with deionized water in an optional water treatment module 890, within the output module 800, as described in U.S. Pat. App. Pub. No. 2017/0317227. In one embodiment, the water treatment module 890 contains a deionized water spray device 860 which is configured to spray the deionized water to the physically exposed surface of the transparent conductive oxide layer 5.

As discussed in detail below, each of the first, second, third, and fourth process modules (200, 300, 400, 500) can deposit a respective material layer to form the photovoltaic cell 10 (shown in FIG. 1) as the web substrate 13 passes through the first, second, third, and fourth process modules (200, 300, 400, 500) sequentially.

The first process module 200 includes a first sputtering target 210, which includes the material of a first electrode, e.g., electrode 2 of the photovoltaic cell 10 illustrated in FIG. 1. A first heater 270 can be provided to heat the web substrate 13 to an optimal temperature for deposition of the first electrode 2. In one embodiment, a plurality of first sputtering sources 210 and a plurality of first heaters 270 may be employed in the first process module 200. In one embodiment, the at least one first sputtering target 210 can be mounted on dual cylindrical rotary magnetron(s), or planar magnetron(s) sputtering sources, or RF sputtering sources. In one embodiment, the at least one first sputtering target 210 can include a molybdenum target, a molybdenum-sodium, and/or a molybdenum-sodium-oxygen target, as described in U.S. Pat. No. 8,134,069, incorporated herein by reference in its entirety.

The portion of the web substrate 13 on which the first electrode 2 is deposited is moved into the second process module 300. A p-doped chalcogen-containing compound semiconductor material is deposited to form the p-doped semiconductor layer 3, such as a sodium doped CIGS absorber layer. In one embodiment, the p-doped chalcogen-containing compound semiconductor material can be deposited employing reactive alternating current (AC) magnetron sputtering in a sputtering atmosphere that includes argon and a chalcogen-containing gas at a reduced pressure. In one embodiment, multiple metallic component targets 310 including the metallic components of the p-doped chalcogen-containing compound semiconductor material can be provided in the second process module 300.

As used herein, the “metallic components” of a chalcogen-containing compound semiconductor material refers to the non-chalcogenide components of the chalcogen-containing compound semiconductor material. For example, in a copper indium gallium selenide (CIGS) material, the metallic components include copper, indium, and gallium. The metallic component targets 310 can include an alloy of all non-metallic materials in the chalcogen-containing compound semiconductor material to be deposited. For example, if the chalcogen-containing compound semiconductor material is a CIGS material, the metallic component targets 310 can include an alloy of copper, indium, and gallium. More than two targets 310 may be used.

At least one chalcogen-containing gas source 320, such as a selenium evaporator, and at least one gas distribution manifold 322 can be provided on the second process module 300 to provide a chalcogen-containing gas into the second process module 300. The chalcogen-containing gas provides chalcogen atoms that are incorporated into the deposited chalcogen-containing compound semiconductor material.

Generally speaking, the second process module 300 can be provided with multiple sets of chalcogen-containing compound semiconductor material deposition units. As many chalcogen-containing compound semiconductor material deposition units can be provided along the path of the web substrate 13 as is needed to achieve the desired thickness for the p-doped chalcogen-containing compound semiconductor material. The number of second vacuum pumps 380 may, or may not, coincide with the number of the deposition units. The number of second heaters 370 may, or may not, be commensurate with the number of the deposition units.

The chalcogen-containing gas source 320 includes a source material for the chalcogen-containing gas. The species of the chalcogen-containing gas can be selected to enable deposition of the target chalcogen-containing compound semiconductor material to be deposited. For example, if a CIGS material is to be deposited for the p-doped semiconductor layer 3, the chalcogen-containing gas may be selected, for example, from hydrogen selenide (H₂Se) and selenium vapor. In case the chalcogen-containing gas is hydrogen selenide, the chalcogen-containing gas source 320 can be a cylinder of hydrogen selenide. In case the chalcogen-containing gas is selenium vapor, the chalcogen-containing gas source 320 can be an effusion cell that can be heated to generate selenium vapor. Each second heater 370 can be a radiation heater that maintains the temperature of the web substrate 13 at the deposition temperature, which can be in a range from 400° C. to 800° C., such as a range from 500° C. to 700° C., which is preferable for CIGS deposition.

The chalcogen incorporation during deposition of the chalcogen-containing compound semiconductor material determines the properties and quality of the chalcogen-containing compound semiconductor material in the p-doped semiconductor layer 3. When the chalcogen-containing gas is supplied in the gas phase at an elevated temperature, the chalcogen atoms from the chalcogen-containing gas can be incorporated into the deposited film by absorption and subsequent bulk diffusion. This process is referred to as chalcogenization, in which complex interactions occur to form the chalcogen-containing compound semiconductor material. The p-type doping in the p-doped semiconductor layer 3 is induced by controlling the degree of deficiency of the amount of chalcogen atoms with respect the amount of non-chalcogen atoms (such as copper atoms, indium atoms, and gallium atoms in the case of a CIGS material) deposited from the metallic component targets 310.

In one embodiment, each metallic component target 310 can be employed with a respective magnetron (not expressly shown) to deposit a chalcogen-containing compound semiconductor material with a respective composition. In one embodiment, the composition of the metallic component targets 310 can be gradually changed along the path of the web substrate 13, so that a graded chalcogen-containing compound semiconductor material can be deposited in the second process module 300. For example, if a CIGS material is deposited as the chalcogen-containing compound semiconductor material of the p-doped semiconductor layer 3, the atomic percentage of gallium of the deposited CIGS material can increase as the web substrate 13 progresses through the second process module 300. In this case, the p-doped CIGS material in the p-doped semiconductor layer 3 of the photovoltaic cell 10 can be graded such that the band gap of the p-doped CIGS material increases with distance from the interface between the first electrode 2 and the p-doped semiconductor layer 3.

In one embodiment, the total number of metallic component targets 310 may be in a range from 3 to 20. In an illustrative example, the composition of the deposited chalcogen-containing compound semiconductor material can be graded such that the band gap of the p-doped CIGS material changes gradually or in discrete steps with distance from the interface between the first electrode 2 and the p-doped semiconductor layer 3.

While the present disclosure is described employing an embodiment in which metallic component targets 310 are employed in the second process module 300, embodiments are expressly contemplated herein in which each, or a subset, of the metallic component targets 310 is replaced with a pair of two sputtering sources (such as a copper target and an indium-gallium alloy target), or with a set of three supper targets (such as a copper target, an indium target, and a gallium target).

According to an aspect of the present disclosure, a sodium-containing material is provided within, or over, the web substrate 13. In one embodiment, sodium can be introduced into the deposited chalcogen-containing compound semiconductor material by employing a sodium-containing metal (e.g., sodium-molybdenum alloy) to deposit the first electrode 2 in the first processing module 200, by providing a web substrate 13 including sodium as an impurity, and/or by providing sodium into layer 3 during deposition by including sodium in the target 310 and/or by providing a sodium containing vapor into the module 300.

The portion of the web substrate 13 on which the first electrode 2 and the p-doped semiconductor layer 3 are deposited is subsequently passed into the third process module 400. An n-doped semiconductor material is deposited in the third process module 400 to form the n-doped semiconductor layer 4 illustrated in the photovoltaic cell 10 of FIG. 1. The third process module 400 can include, for example, a third sputtering target 410 (e.g., a CdS target) and a magnetron (not expressly shown). The third sputtering target 410 can include, for example, a rotating AC magnetron, an RF magnetron, or a planar magnetron. A heater 470 may be located in the module 400.

Subsequently, an n-type semiconductor layer 4, such as an n-type CdS window layer is deposited over the p-type absorber layer 3 to form a p-n junction. Sodium atoms diffuse from the web substrate 13 and/or from the first electrode 2 into the deposited semiconductor materials to form a material stack 3, 4 including sodium at the atomic concentration greater than 1×10¹⁹/cm³. Specifically, sodium provided in the first electrode 2 or in the web substrate 13 can diffuse into the deposited chalcogen-containing compound semiconductor material during deposition of the chalcogen-containing compound semiconductor material. The sodium concentration in the deposited chalcogen-containing compound semiconductor material can be in a range from 1.0×10¹⁹/cm³ to 5×10²⁰/cm³. The sodium atoms tend to pile up at a high concentration near the growth surface of the chalcogen-containing compound semiconductor material, thereby causing the sodium atoms to travel forward as the deposition process progresses.

Thus, a material stack 3, 4 including a p-n junction is formed on the web substrate 13. In one embodiment, the material stack 3, 4 can comprise a stack of a p-doped metal chalcogenide semiconductor layer (as the p-doped semiconductor layer 3) and an n-doped metal chalcogenide semiconductor layer (as the n-doped semiconductor layer 4). In one embodiment, the p-doped metal chalcogenide semiconductor layer can comprise copper indium gallium selenide (CIGS), and the n-doped metal chalcogenide semiconductor layer can comprise a material selected from a metal selenide, a metal sulfide (e.g., CdS), and an alloy thereof. The material stack 3, 4 can include sodium at an atomic concentration greater than 1×10¹⁹/cm³ (such as about 1×10²⁰/cm³).

The portion of the web substrate 13 on which the first electrode 2, the p-doped semiconductor layer 3, and the n-doped semiconductor layer 4 are deposited is subsequently passed into the fourth process module 500. A transparent conductive oxide material is deposited in the fourth process module 500 to form the second electrode comprising a transparent conductive layer 5 illustrated in the photovoltaic cell 10 of FIG. 1. The fourth process module 400 can include, for example, a fourth sputtering target 510, a heater 570, and a magnetron (not expressly shown). The fourth sputtering target 510 can include, for example, a ZnO, AZO or ITO target and a rotating AC magnetron, an RF magnetron, or a planar magnetron. A transparent conductive oxide layer 5 is deposited over the material stack 3, 4 including the p-n junction. In one embodiment, the transparent conductive oxide layer 5 can comprise a material selected from tin-doped indium oxide, aluminum-doped zinc oxide, and zinc oxide. In one embodiment, the transparent conductive oxide layer 5 can have a thickness in a range from 60 nm to 1,800 nm.

Subsequently, the web substrate 13 passes into the output module 800. In one embodiment, the deionized water can be applied to the physically exposed surface of the transparent conductive oxide layer 5 by spraying as illustrated in FIG. 5. The spraying operation can be performed employing at least one spray device 860 configured to spray the fluid, such as deionized water, on the physically exposed surface of the transparent conductive oxide layer 5 located over the front surface of the processed web substrate 13. The spray device 860 may comprise one or more nozzles or shower heads, such as one or more rows of nozzles, which spray water onto layer 5 located over the web substrate 13. Gravity may be employed to retain the sprayed deionized water on the surface of the transparent conductive oxide layer 5. For example, the web substrate 13 may be at an incline such that the deionized water stays on the surface of the transparent conductive oxide layer 5.

The positions of the various output-side rollers 820 can be adjusted to retain the sprayed deionized water on the surface of the transparent conductive oxide layer 5. A deionized water tank 850 can be employed as a reservoir of the deionized water to be supplied to the at least one spray device 860. Alternatively, a water pipe connected to an ion exchange resin or electrodeionization apparatus may be used instead of the deionized water tank 850 to supply deionized water to the spray device 860 (e.g., nozzle(s) or shower head(s)).

At least one dryer 870 can be employed to remove residual deionized water from the surface of the transparent conductive oxide layer 5. The dryer 870 may comprise a fan or blower configured to blow filtered air (or inert gas such as nitrogen) toward the surface of the transparent conductive oxide layer 5. In one embodiment, the direction of the filtered air from the at least one dryer 870 can be directed to push the residual deionized water off the front surface of the transparent conductive oxide layer 5 in conjunction with the gravitational force, for example, by directing the air flow downward and/or outward (away from the center of the web substrate 13). Alternatively, the dryer 870 may comprise a heater which evaporates the water in addition to or instead of the fan or blower. The web substrate 13 can then be wound onto the output spool 810.

In one embodiment, deionized water can be applied to the physically exposed surface of the transparent conductive oxide layer for long enough time to allow bulk diffusion of sodium atoms from within the bulk (i.e., interior) of the transparent conductive oxide layer 5 to reach the outer surface of layer 5 to be rinsed off the outer surface. Sodium is a fast diffuser within the transparent conductive oxide layer 5, the p-doped semiconductor layer 3 and the n-doped semiconductor layer 4. In one embodiment, the deionized water can be applied to the physically exposed surface of the transparent conductive oxide layer for a duration in a range from 5 seconds to 10 minutes. In one embodiment, the deionized water can be applied to the physically exposed surface of the transparent conductive oxide layer for a duration in a range from 20 seconds to 3 minutes.

In one embodiment, the deionized water is applied at an elevated temperature greater than 50 degrees Celsius. In one embodiment, the deionized water is applied at an elevated temperature in a range from 50 degrees Celsius to 100 degrees Celsius. In one embodiment, the deionized water is applied at an elevated temperature in a range from 60 degrees Celsius to 95 degrees Celsius. In one embodiment, the deionized water is applied at an elevated temperature in a range from 70 degrees Celsius to 80 degrees Celsius. In one embodiment, a fluid heater 874 (e.g., a resistive heater) and/or a substrate heater 872 may be employed to maintain the temperature of the fluid (e.g., water provided from the spray device 860) and/or of the web substrate 13 at an elevated temperature in a range from 50 degrees Celsius to 100 degrees Celsius. The fluid heater may be located adjacent to the tank 850 and/or adjacent to the spray device 860 to heat the fluid being provided from the tank 850 through the spray device 860 over the moving web substrate 13. In the alternative, water treatment module 890 may be omitted and/or the output unit 800 may include a web cutter configured to cut the web substrate 13 into substrate 12 sheets.

Another aspect of this invention is related to subjecting the photovoltaic cell to a thermal annealing step, which could be applied before, after or even instead of the water treatment step. This annealing step may lead to a further reduction of Na concentration in the cell. In addition, the thermal annealing step leads to a significant reduction in free carrier concentration which is an important factor in defining solar cell performance.

While sputtering was described as the preferred method for depositing all solar cell layers onto the web substrate 13, some layers may be deposited by MBE, CVD, evaporation, plating, etc.

### Battery Formation

After the solar cell material layers are formed on a first surface of the web substrate 13, the batteries 30 may be formed on an opposing second surface of at least a portion of the web substrate 13. The batteries 30 may be formed on the second surface of the web substrate 13 before the web substrate 13 is cut, or the batteries may be formed on the second surface of sheets cut from the web substrate 13, such as the substrate 12 sheets shown in FIG. 1, or sheets including multiple connected substrate 12 sheets. Thus, the batteries 30 may be formed before or after cutting the web substrate 13, while the solar cells 10 are preferably formed on the web substrate 13 prior to cutting the web substrate 13 into sheets.

In one embodiment, the batteries 30 may be printed on the web substrate 13 by screen-printing, gravure printing, pad printing, inkjet printing, flexographic coating, spray coating, ultrasonic spray coating, or slot die coating. However, the present disclosure is not limited to any particular type of printing method.

According to various embodiments, the printing may comprise printing (e.g., dispensing, pressing, or spraying) an ink for fabricating one or more layers of the batteries 30. Desirable materials can be mixed together to form, for example, solutions, suspensions, melts, or slurries, which can be used as “ink” in the printing process. Each layer may be formed using a different ink.

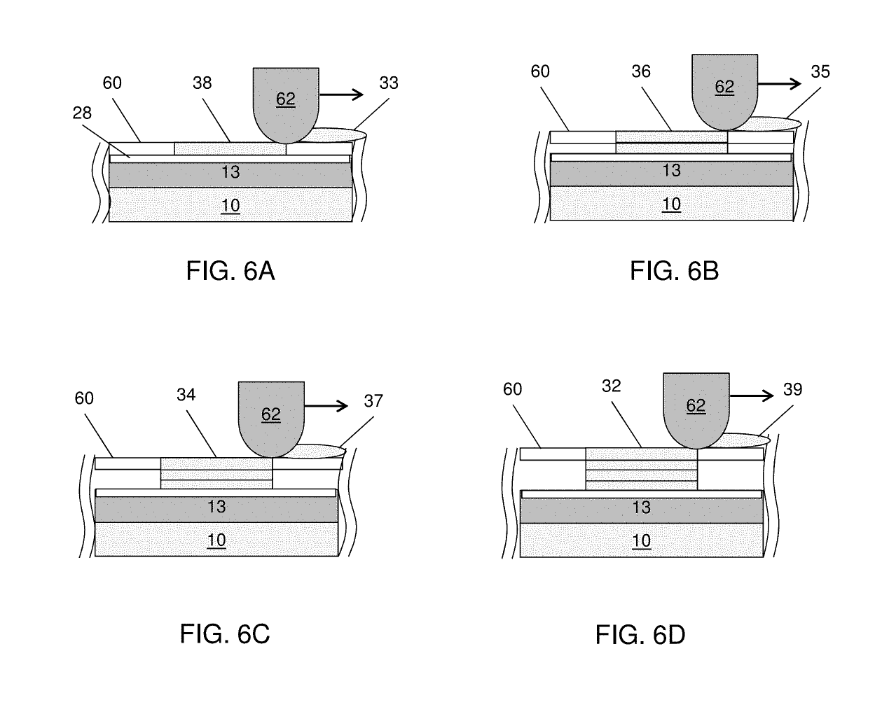

FIGS. 6A-6D illustrate a screen printing method of forming batteries 30 on a web substrate 13, according to various embodiments of the present disclosure. While the batteries 30 are described as being formed on the web substrate 13, the present method is not limited thereto. For example, the method may include forming the batteries 30 on sheets cut from the web substrate 13, such as the substrate 12 shown in FIG. 1, or sheets including multiple connected substrates 12.

Referring to FIG. 6A, the method includes disposing a silk screen 60 over the second (e.g., bottom) surface of the web substrate 13 covered with the cover dielectric layer 28. The web substrate 13 has an opposing first surface upon which a solar cell 10 is formed. A current collector ink 33 may be applied to the silk screen 60 using a squeegee 62, such that layers of the current collector ink 33 are deposited on the web substrate 13 through corresponding openings in the mask 60. The layers of current collector ink 33 may be dried to form the current collectors 38.

Referring to FIG. 6B, the method may include disposing a silk screen 60 over the second surface of the web substrate 13. A cathode ink 35 may be applied to the silk screen 60 using the squeegee 62, such that cathode ink 35 layers are formed on corresponding current collectors 38. The cathode ink 35 layers may then be dried to form one or more cathode layers 36.

Referring to FIG. 6C, the method may include disposing a silk screen 60 over the second surface of the web substrate 13. An electrolyte ink 37 may be applied to the silk screen 60 using the squeegee 62, such that electrolyte ink 37 layers are formed on corresponding cathode layers 36. The electrolyte ink 37 layers may then be dried to form one or more electrolytes 34.

Referring to FIG. 6D, the method may optionally include disposing a silk screen 60 over the second surface of the web substrate 13. An anode ink 39 may be applied to the silk screen 60 using the squeegee 62, such that anode ink 39 layers are formed on corresponding electrolyte 34. The anode ink 39 layers may be dried to form one or more anodes 32. The web substrate 13 may then be cut into strips to form devices 100 as shown FIG. 1.

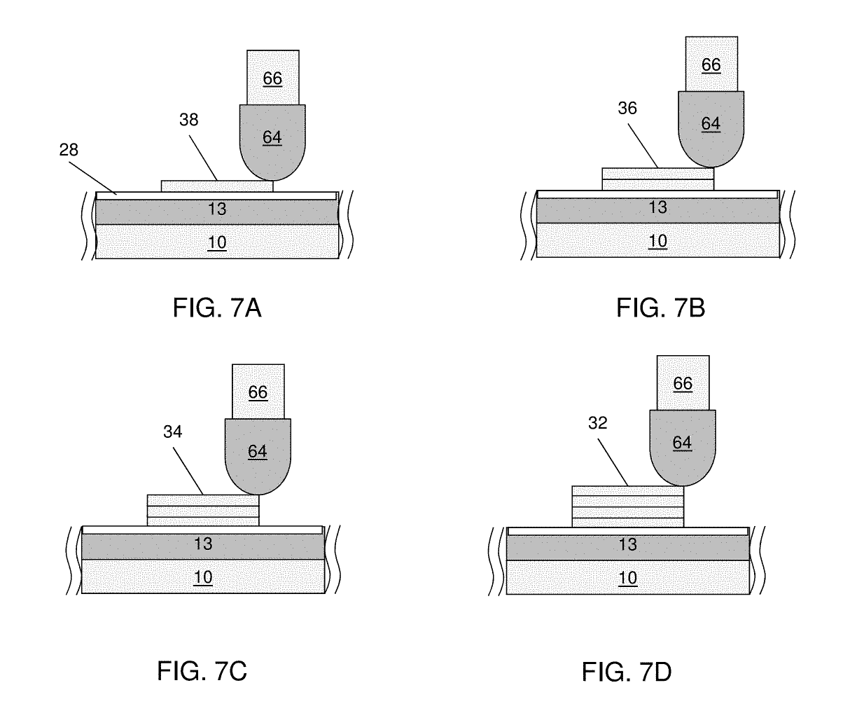

FIGS. 7A-7D illustrate an inkjet printing method of forming a battery 30 on a web substrate 13, according to various embodiments of the present disclosure. While the batteries 30 are described as being formed on the web substrate 13, the present method is not limited thereto. For example, the method may include forming the batteries 30 on sheets cut from the web substrate 13, such as the substrate 12 shown in FIG. 1, or sheets including multiple connected substrates 12.

Referring to FIG. 7A, the method includes using an inkjet print head 64 to deposit current collector ink over the second (e.g., bottom) surface of the web substrate 13 covered with the cover dielectric layer 28. The web substrate 13 has an opposing first surface upon which a solar cell 10 is formed. The print head 64 may be connected to an ink reservoir 66, which may include the current collector ink and other inks used to form layers the battery 30. The current collector ink may be applied to multiple discrete areas of the web substrate 13. The current collector ink may be dried to form one or more current collectors 38 over the cover dielectric layer 28 located on the back side of the web substrate 13.

Referring to FIG. 7B, the method may include using the inkjet print head 64 to deposit a cathode ink on the web substrate 13 and drying the cathode ink, such that one or more cathode layers 36 are formed on one or more previously formed corresponding current collectors 38.

Referring to FIGS. 7C and 7D, the method can be repeated to form one or more electrolyte layers 34 on the cathode layers 36, and to form one or more anode layers 32 on the electrolyte layers 34. The web substrate 13 may then be cut into strips to form devices 100 as shown FIG. 1.

In an alternative embodiment, the order for forming the anode layer 32 and the cathode layers 36 of the batteries 30 may be reversed to form the anode layers 32 on the web substrate 13 side of the batteries 30 (e.g., the anode layers 32 are formed over the web substrate 13 first, followed by forming the electrolyte layers 34 on the anode layers 32 followed by forming the cathode layers 36 on the electrolyte layers 34).

### PPGS Array Formation

An interconnect 25 may then be applied to the solar cell 10 of each PPGS device 100. The devices 100 may be electrically connected in series to one another by stacking or tiling the devices 100, as described above, with the interconnects 25 physically and electrically connecting adjacent devices 100 to form photovoltaic power generation and storage modules.

The bus bars 40, 42, 44, 46, 48 may be formed on the tiled devices 100 to form an array 110. For example, dielectric layers may include openings through which bus bars may be electrically connected to corresponding portions of the devices 100. For example, the dielectric layer 28 may include the opening 28A exposing the back side of the substrate 12. The opening 28A may be formed by cutting or etching the dielectric layer 28.

The bus bars 40, 42, 44, 46, 48 may be formed using a conductive ink. The conductive ink may be deposited using a variety of deposition methods, such as ink jet printing, screen printing, flexographic printing, slot die coating, or the like. As an alternative to a conductive ink, the bus bars 40, 42, 44, 46, 48 may be made via a foil connection (e.g. aluminum, stainless steel, nickel foil, etc.) using foil die cutting, cold foil, or hot foil printing methods. The bus bars 40, 42, 46 may be connected to a control unit 50 to complete a PPGS array 110.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the photovoltaic cells of the embodiments of the present disclosure.

What is claimed is:

1. A photovoltaic power generation and storage (PPGS) device comprising:
an electrically conductive substrate;
a solar cell disposed on a first side of the substrate, the solar cell comprising an absorber layer disposed between an anode and a cathode; and
a solid-state battery printed on an opposing second side of the substrate, the battery comprising an electrolyte layer disposed between an anode and a cathode.

2. The device of claim 1, wherein the substrate is a flexible substrate.

3. The device of claim 1, further comprising a dielectric layer disposed between the battery and the second side of the substrate,
wherein the solar cell anode directly, physically contacts the first side of the substrate.

4. The device of claim 1, further comprising an interconnect comprising:
an electrically conductive wire having a first portion disposed on the solar cell cathode and a second portion that extends from the solar cell beyond an edge of the substrate;
a first dielectric layer covering the first portion of the wire; and
a second dielectric layer disposed on the second portion of the wire.

5. The device of claim 4, further comprising:
a third dielectric layer disposed between the battery and the second side of the substrate; and
a fourth dielectric layer covering the battery.

6. The device of claim 4, wherein the wire is disposed in a serpentine pattern.

7. The device of claim 1, wherein:
the battery anode comprises zinc, aluminum, magnesium, yttrium, or any combination thereof;
the battery cathode comprises vanadium pentoxide (V₂O₅) particles, manganese dioxide (MnO₂) particles, cobalt oxide (CoOₓ) particles, lead oxide (PbOₓ) particles, or any combination thereof; and
the electrolyte layer comprises a polymer impregnated with an ionic liquid.

8. The device of claim 7, wherein the battery further comprises a current collector disposed on the cathode of the battery.

9. The device of claim 1, wherein:
the absorber layer comprises p-type doped copper indium gallium selenide material;
the solar cell cathode comprises a transparent conductive material;
the solar cell anode comprises a conductive metal; and
the solar cell further comprises a buffer layer comprising n-doped semiconductor material, disposed between the absorber layer and the cathode.

10. A photovoltaic power generation and storage (PPGS) array comprising:
an array of tiled PPGS devices of claim 1;
interconnects electrically connecting the solar cells of the PPGS devices in series;
a first bus line electrically connected to the cathode of the solar cell of a first one of the PPGS devices;
a second bus line electrically connected to the anode of the solar cell of a last one of the PPGS devices, via the substrate of the last PPGS device;
third bus lines electrically connecting adjacent batteries in series;
a fourth bus line electrically connected to the cathode of the battery of the last PPGS device;
a fifth bus line electrically connecting the cathode of the solar cell of the first PPGS device and the anode of the battery of the first PPGS device; and
a control unit electrically connected to the second and fourth bus lines and configured to control whether power generated by the solar cells is stored in the batteries or is applied to the a load that is electrically connected to the first bus line, and to control whether power stored in the batteries is applied to the load.

11. The PPGS array of claim 10, wherein the interconnects each comprise:
an electrically conductive wire having a first portion disposed on the solar cell cathode and a second portion that extends from the solar cell beyond an edge of the substrate;
a dielectric layer disposed the first portion of the wire; and
a dielectric layer disposed on the second portion of the wire.

12. The PPGS array of claim 10, wherein the first bus bar serves as an electrical terminal for both the solar cells and the batteries.

13. The PPGS array of claim 10, further comprising a dielectric layer disposed between the batteries and the substrates of the PPGS devices.

14. The PPGS array of claim 13, further comprising a dielectric layer at least partially covering the batteries and the first, second and third bus lines.

15. A method of making a photovoltaic power generation and storage (PPGS) array, the method comprising:
forming a semiconductor material stack including a solar cell p-n junction on a first surface of a conductive web; and
printing solid-state batteries on an opposing second surface of at least a portion of the conductive web.

16. The method of claim 15, further comprising:
dividing the conductive web substrate to form PPGS devices that each comprise a solar cell and one of the batteries disposed on opposing sides of a conductive substrate;
attaching an interconnect to each of the PPGS devices, each interconnect comprising a conductive wire having a first portion that is electrically connected to the solar cell and a second portion that extends from the solar cell beyond an edge of the substrate;
assembling the PPGS devices into an array, such that the solar cells are electrically connected in series by the interconnects;
forming a first bus line on a the array, such that the first bus line operates as a negative terminal for the solar cells;
forming a second bus line on the array, such that the second bus line operates as a positive terminal for the solar cells;
forming third bus lines on the array, such that the third bus lines electrically connect the batteries in series;
forming a fourth bus line on the array, such that the fourth bus line operates as a positive terminal for the batteries;
forming a fifth bus line on the array, such that the fifth bus line electrically connects the batteries to the first bus line, such that the first bus line operates as a negative terminal for the batteries and the solar cells;
electrically connecting the second and fourth bus lines to a control unit configured to selectively control whether power generated by the solar cells is stored in the batteries or is applied to a load electrically connected to the first bus line, and to control whether power stored in the batteries is applied to the load.

17. The method of claim 15, wherein the printing comprises screen-printing, gravure printing, pad printing, inkjet printing, flexographic coating, spray coating, ultrasonic spray coating, slot die coating, or any combination thereof.

18. The method of claim 17, wherein the printing comprises screen printing or inkjet printing.

19. The method of claim 16, further comprising:
forming a first dielectric layer on the second surface of the conductive web; and
forming a second dielectric layer on the batteries and the first, second and third bus lines.

20. The method of claim 19, wherein:
the second bus line contacts at least one of the substrates through an opening formed in the first dielectric layer; and
the first and fifth bus lines extend around an edge of the array to contact one of the interconnects.

21. The method of claim 15, further comprising:
cutting the web substrate into sheets before the printing; and
printing the batteries on second surfaces of the sheets.
